(19) United States
(12) Patent Application Publication
(10) Pub. No.: US 2014/0111921 A1
(43) Pub. Date: Apr. 24, 2014

(54) Zr-Based Amorphous Alloy

(71) Applicant: Huawei Technologies Co., Ltd., Shenzhen (CN)

(72) Inventors: Tao Zhang, Shenzhen (CN); Chen Chen, Shenzhen (CN); Enhuai Yin, Shenzhen (CN); Liang Fu, Shenzhen (CN); Ailan Zhu, Shenzhen (CN)

(73) Assignee: Huawei Technologies Co., Ltd., Shenzhen (CN)

(21) Appl. No.: 14/145,289

(22) Filed: Dec. 31, 2013

Related U.S. Application Data
(63) Continuation of application No. PCT/CN2013/073788, filed on Apr. 7, 2013.

(30) Foreign Application Priority Data
Oct. 19, 2012 (CN) 201210400725.0

(51) Int. Cl. C22C 45/10; H05K 7/02

(52) U.S. Cl. CPC C22C 45/10; H05K 7/02
USPC 361/679.01; 148/403; 164/61; 164/66.1

(57) ABSTRACT

A Zr-based amorphous alloy is provided; the formula of the Zr-based amorphous alloy is (Zr,Hf,Nb)ₐCu_{b}Ti_{c}Al_{d}Reₑ, where a, b, c, d, and e are corresponding atomic percent content of elements in the Zr-based amorphous alloy, 40≦a≦65, 20≦b≦50, 0.1≦c≦10, 5≦d≦15, 0.05≦e≦5, a+b+c+d+e≦100, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu.

### CROSS-REFERENCE TO RELATED APPLICATIONS

This application is a continuation of International Application No. PCT/CN2013/073788, filed on Apr. 7, 2013, which claims priority to Chinese Patent Application No. 201210400725.0, filed on Oct. 19, 2012 both of which are hereby incorporated by reference in their entireties.

### TECHNICAL FIELD

The present application relates to the field of metal alloys, and in particular, to a Zr-based amorphous alloy.

### BACKGROUND

Due to a lack of a long-range order of an atomic arrangement of an amorphous alloy, neither dislocation nor grain boundary exists in the structure of the alloy. Therefore, compared with ordinary polycrystalline metal materials, amorphous alloys have merits such as high intensity, corrosion resistance, and abrasion resistance, and may be used as raw materials for manufacturing microelectronic devices, sports utilities, luxury goods, consumer electronics, and the like. A general method for manufacturing an amorphous alloy is to cool an alloy melt quickly to be below a glass transformation temperature (T_{g}) at a certain cooling speed. The extremely fast cooling speed avoids crystal nucleation and growth, and finally accomplishes a completely amorphous structure. If the cooling speed required for turning a material into an amorphous structure is lower, it is easier to form a large-sized amorphous structure of the material. In alloy systems such as Zr-based, palladium-based, magnesium-based, iron-based, copper-based, and lanthanum-based alloy systems, the critical cooling speed of specific alloys is less than 10 degrees Kelvin (K)/second in magnitude, and bulk amorphous alloys of a thickness of a centimeter magnitude may be manufactured through copper mold casting.

Generally, a critical diameter that can form a cast round bar of a completely amorphous structure is used as glass forming ability (GFA) of the alloy. The glass forming ability of the alloy primarily depends on chemical components of the alloy. Complexity and diversity of the alloy components can reduce the critical cooling speed of forming the amorphous structure and improve the glass forming ability of the alloy. Among them, a multi-element Zr-based amorphous alloy is an amorphous alloy that has been discovered so far having a good glass forming ability and superb mechanical and machining properties, and taking on the best application prospect of structural materials.

The Zr-based amorphous alloys that have been developed so far for forming an amorphous structure in the world centrally exist in the Zr-TM-Al or Zr-TM-Be (TM is Ti, Cu, Ni, or Co) system. With certain components of such alloys, a melt may cool down to form an amorphous round bar material of a diameter greater than 10 millimeters (mm). Currently, the manufacturing of such alloys occurs primarily in labs. The oxygen content in an alloy is generally less than 200 parts per million (ppm). Therefore, the oxygen content existent in the raw material and introduced in the manufacturing process must be controlled strictly.

For example, the following alloy formula can form an amorphous structure of a certain size after being cast:

(Zr and/or Hf)ₐM_{b}Al_{c}

where M is Ni, Cu, Fe, Co, or any combination thereof, a, b, and c are atomic percents, 25≦a≦85, 5≦b≦70, and 0<c≦35. Preferably, after vacuum melting and ordinary copper mold casting, the Zr₅₀Cu₄₀Al₁₀ alloy can form a completely amorphous round bar of a 10 mm diameter, that is, have a glass forming ability of 10 mm.

To further enhance the glass forming ability of the alloy, a proper amount of Ni is generally added into the alloy, and combines with Cu into a specific formula. For example, after 5 atomic percent (at. %) of Ni is added into the alloy, a four-element Zr₅₅Cu₃₀Ni₅Al₁₀ alloy is obtained, whose glass forming ability is up to 30 mm. A general manufacturing method is as follows: Place a specific quantity of raw materials of a specific formula into a vacuum smelting furnace, adjust the vacuum degree to 5×10⁻³ Pascal (Pa), and then charge with 0.05 MegaPascal (MPa) argon as protection gas; after homogeneous smelting and cooling with the furnace, obtain a master alloy; subsequently, place the master alloy into an induction furnace for re-melting, and then spray and cast the master alloy into a copper mold to obtain amorphous alloy bars.

The GFA of a Zr-based alloy in the prior art is very sensitive to oxygen content of the alloy. Because cohesion of Zirconium and oxygen occurs very easily, zirconium oxide or zirconium/oxygen clusters can be generated easily in the alloy melt. They may serve as a core of non-homogeneous nucleation, and reduce the GFA of the alloy. Under ordinary laboratory or industrial conditions, a certain amount of oxygen is inevitably introduced into the Zr-based amorphous alloy. Therefore, expensive high-purity raw materials have to be used in the production process, and a high vacuum degree is required in the smelting and casting processes. The required vacuum degree is over 10⁻² Pa or even 10⁻³ Pa to prevent decrease of the amorphous GFA caused by high oxygen content in the alloy. High-purity (a purity of over 99.9%) raw materials and stringent protection atmosphere lead to very high costs of manufacturing a Zr-based amorphous alloy, and make mass production impracticable. Ordinary industrial raw materials in the market are not good enough for manufacturing components and products of an amorphous structure of specific dimensions.

### SUMMARY

Embodiments of the present application provide a Zr-based amorphous alloy that ensures the capability of forming an amorphous bulk on the basis of lower process requirements such as a lower material purity and a lower casting environment vacuum degree.

An embodiment of the present application provides a Zr-based amorphous alloy, where the Zr-based amorphous alloy has the following formula:

(Zr,Hf, and/or Nb)ₐCu_{b}Ti_{c}Al_{d}Reₑ,

where a, b, c, d, and e are corresponding atomic percent content of elements in the Zr-based amorphous alloy, 40≦a≦65, 20≦b≦50, 0.1≦c≦10, 5≦d≦15, 0.05≦e≦5, a+b+c+d+e≦100, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu.

A method for manufacturing a Zr-based amorphous alloy, including: melting metal raw materials completely under a protection atmosphere or vacuum condition, and then performing casting, cooling, and molding to form a Zr-based amorphous alloy, where the Zr-based amorphous alloy has the following formula:

(Zr,Hf, and/or Nb)ₐCu_{b}Ti_{c}Al_{d}Reₑ,

where a, b, c, d, and e are corresponding atomic percent content of elements in the Zr-based amorphous alloy, 40≦a≦65, 20≦b≦50, 0.1≦c≦10, 5≦d≦15, 0.05≦e≦5, a+b+c+d+e≦100, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu.

An electronic device, including a casing and electronic components placed in the casing, where the casing is made of a Zr-based amorphous alloy, and the Zr-based amorphous alloy has the following formula:

(Zr,Hf, and/or Nb)ₐCubTi_{c}Al_{d}Reₑ,

where a, b, c, d, and e are corresponding atomic percent content of elements in the Zr-based amorphous alloy, 40≦a≦65, 20≦b≦50, 0.1≦c≦10, 5≦d≦15, 0.05≦e≦5, a+b+c+d+e≦100, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu.

In the embodiments of the present application, trace quantities of rare earth elements (0.05-5 atomic percent) are added into an alloy to suppress a crystallization trend and improve melt stability; the rare earth elements can absorb oxygen in the alloy, adjust oxygen content of the alloy, suppress heterogeneous nucleation, avoid crystallization of liquid metal in a cooling process, enhance glass forming ability of the alloy, thereby widening the choice range of raw materials required for manufacturing an amorphous alloy. Moreover, a product of a high glass forming ability can be manufactured without using high-purity raw materials, and we can further reduce process requirements such as vacuum degree, which slashes production costs.

### BRIEF DESCRIPTION OF DRAWINGS

To illustrate the technical solutions in the embodiments of the present application more clearly, the following briefly introduces the accompanying drawings required for describing the embodiments. The accompanying drawings in the following description show merely some embodiments of the present application, and a person of ordinary skill in the art may still derive other drawings from these accompanying drawings without creative efforts.

FIG. 1 is an X-ray diffraction (XRD) analysis result diagram of a Zr-based amorphous alloy of two components according to an embodiment of the present application; and

FIG. 2 is a schematic diagram of an electronic device according to Embodiment 8 of the present application.

### DESCRIPTION OF EMBODIMENTS

The following clearly describes the technical solutions in the embodiments of the present application with reference to the accompanying drawings in the embodiments of the present application. The described embodiments are merely a part rather than all of the embodiments of the present application. All other embodiments obtained by a person of ordinary skill in the art based on the embodiments of the present application without creative efforts shall fall within the protection scope of the present application.

The present application provides an easily formable Zr-based amorphous alloy, where the Zr-based amorphous alloy of an amorphous structure may be subjected to an ordinary copper mold casting method or a conventional parts casting method to generate amorphous bulk materials or parts of an amorphous structure. The Zr-based amorphous alloy includes Zr, Ti, Cu, Al, and one or more elements of rare earth, in which Zr may be partly replaced with Hf, and Cu may be partly or completely replaced with Ni. An atomic percent of each element in the final amorphous alloy fulfills the following general formula:

(Zr,Hf, and/or Nb)ₐCu_{b}Ti_{c}Al_{d}Reₑ,

where a, b, c, d, and e are corresponding atomic percent content of elements in the amorphous alloy, 40≦a≦65, 20≦b≦50, 0.1≦c≦10, 5≦d≦15, 0.05≦e≦5, a+b+c+d+e≦100, Re is one or more elements of rare earth, that is, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu. The Re element group may be obtained by adding mishch metal (Misch Metal, expressed by MM in the molecular formula). In some embodiments, the Re is preferably one or a combination of plural ones selected from a group of elements La, Nd, Dy, Er, Tm, and Yb.

For example, in some embodiments, the Zr-based amorphous alloy may include the following components: Zr_{48.7}Hf₁Ti₂Cu_{37.8}Al₁₀Er_{0.5}, Zr_{48.7}Hf₁Ti₂Cu_{37.8}Al₁₀(Y and/or Er)_{0.5}, Zr_{48.7}Hf₁Ti₂Cu_{37.81}Al₁₀(Y and/or MM)_{0.5}, Zr₅₉Ti₂Cu₂₅₁Al₁₂Er₂, Zr₅₇Ti2Cu₃₀1Al₁₀La₁, Zr₅₇Ti₁Cu₃₁₁Al₉Gd₂, Zr₅₈Cu₂₅Al₁₂Ti₂Hf₁Er₂, Zr₅₉Cu₂₅Al₁₂Ti₁Nb₁Er₂, Zr_{59.5}Hf₁Ti₂Cu₂₅₁Al₁₂Er_{0.5}, and the like.

With the Zr-based amorphous alloy in the foregoing range of components, an alloy ingot of a bar shape, granule shape, or strip shape may be obtained first through arc melting or induction melting by using low-purity raw materials at a low vacuum degree (lower than 1×10⁻³ Pa), and then the alloy ingot is re-melted or cast at a low vacuum degree (lower than 1×10⁻² Pa) to obtain an amorphous bar or amorphous part of a relatively large size.

The present application provides a method for manufacturing a Zr-based amorphous alloy of the foregoing molecular formula. The method includes: preparing components in the foregoing (Zr, Hf, and/or Nb)ₐCu_{b}Ti_{c}Al_{d}Reₑ Zr-based amorphous alloy according to a molecular ratio within a range of a, b, c, d, and e in the alloy, where 40≦a≦65, 20≦b≦50, 0.1≦c≦10, 5≦d≦15, 0.05≦e≦5, and a+b+c+d+e≦100; melting such components into a master alloy until they are fully blended homogeneously; and performing casting and cooling for the master alloy to obtain an amorphous bar formed of the Zr-based amorphous alloy. The casting may be pouring, suction casting, or spray casting. For example, the Zr-based amorphous alloy in the present application may have any one of the components listed in Table 1:

TABLE 1

| Serial Number | Alloy Component |
|---|---|
| 1 | Zr_{48.7}Hf₁Ti₂Cu_{37.8}Al₁₀(Y and/or Er)_{0.5} |
| 2 | Zr_{49.7}Ti₂Cu_{38.1}Al₁₀Er_{0.1}Y_{0.1} |
| 3 | Zr₅₀Hf₈Ti₂Cu₂₅Al₁₀La₅ |
| 4 | Zr₅₀Hf₁Ti₂Cu₃₅₁Al₉Ce₃ |
| 5 | Zr_{48.7}Hf₁Ti₂Cu_{37.8}Al₁₀Re_{0.5} |
| 6 | Zr_{62.85}Ti_{0.2}Cu₂₀Al₁₅Er₂ |
| 7 | Zr₄₀Ti₁₀Cu₃₉Al₁₀La₁ |
| 8 | Zr₅₇Ti₁Cu₃₁Al₉Gd₂ |
| 9 | Zr_{48.7}Hf_{0.6}Cu_{38.45}Ti₂Al₁₀Er_{0.25} |
| 10 | Zr_{60.5}Ti₂Cu₂₅Al₁₂Er_{0.5} |
| 11 | Zr_{60.5}Hf_{0.8}Ti_{1.2}Cu₂₅Al₁₂Er_{0.5} |
| 12 | Zr₅₉Cu₂₅Al₁₂Ti₁Nb₁Er₂ |
| 13 | Zr_{59.5}Hf₁Ti₂Cu₂₅Al₁₂Er_{0.5} |
| 14 | Zr_{62.85}Cu₂₂Al₁₅Ti_{0.1}Er_{0.05} |
| 15 | Zr₄₀Cu_{42.9}Al₁₅Ti_{0.1}Er₂ |
| 16 | Zr₆₅Cu₂₀Al_{12.9}Ti_{0.1}Er₂ |
| 17 | Zr₄₀Cu₅₀Al_{9.8}Ti_{0.1}Re_{0.1} |
| 18 | Zr₄₀Cu₃₀Al₁₅Ti₁₀La₅ |
| 19 | Zr₅₅Cu₂₀Al₁₀Ti₁₀Ce₅ |
| 20 | Zr₄₀Cu₄₀Al₈Ti₁₀Er₂ |
| 21 | Zr₅₅Ti₁₀Cu₂₅Al₅Er₅ |
| 22 | Zr₄₀Cu₄₀Al5Ti₁₀Nd₅ |
| 23 | Zr₆₀Cu₂₅Al₁₀Ti_{0.1}Hf_{2.9}Er₂ |
| 24 | Zr₆₁Cu₂₅Al₁₀Ti_{0.1}Nb_{1.9}Sc₂ |
| 25 | Zr_{57.9}Cu₂₅Ni₅Al₁₀Ti_{0.1}Sc₂ |
| 26 | Zr₄₉Cu₃₈Al₁₀Ti₂Er₁ |
| 27 | Zr₆₀Ti₂Cu₂₅Al₁₂Dy₁ |
| 28 | Zr_{49.7}Cu_{37.8}Al₁₀Ti₂Tm_{0.5} |
| 29 | Zr₅₀Cu37Al₁₀Ti₂Yb₁ |
| 30 | Zr_{60.5}Ti₂Cu₂₅Al₁₂Tm_{0.5} |
| 31 | Zr_{60.5}Ti_{1.5}Cu₂₅Al₁₂Yb₁ |
| 32 | Zr_{60.5}Hf_{0.8}Ti_{1.2}Cu₂₅Al₁₂Nd_{0.5} |
| 33 | Zr₄₉Hf₁Cu₃₇Al₁₀Ti₂Tm₁ |
| 34 | Zr₅₉Nb₁Cu₂₅Al₁₂Ti₂Tm₁ |
| 35 | Zr₅₉Nb₁Cu₂₅Al₁₂Ti₁Yb₂ |
| 36 | Zr₄₉Ti₂Cu₃₆Ni₂Al₁₀Er₁ |
| 37 | Zr_{49.5}Ti₂Cu₃₆Ni₂Al₁₀Tm_{0.5} |
| 38 | Zr₆₀Ti₂Cu₂₄Ni₁Al₁₂Er₁ |
| 39 | Zr₄₉Ti₂Cu₃₆Ni₂Al₁₀Dy₁ |
| 40 | Zr_{60.5}Ti₂Cu₂₄Ni₁Al₁₂Nd_{0.5} |
| 41 | Zr_{59.5}Ti₂Cu₂₅Al₁₂Er_{0.5}Tm_{0.5}Y_{0.5} |
| 42 | Zr₅₀Ti₁Cu₃₆Ni_{2.5}Al₁₀Yb_{0.5} |

The method for manufacturing a Zr-based amorphous alloy may include the following steps:

Step 1: Components Preparation

Components are prepared within the range of the formula at a specific atomic percent. For example, components are prepared according to each component and a specific atomic percent in Table 1.

In the preparation process, components of the alloy may be prepared according to the components and atomic percents in Table 1 by using materials such as metal rods, blocks, ingots and plates made of elements Zr, Hf, Ti, Cu, Al, Er, and the like, with a purity of 99.5%.

Step 2: Melting

The prepared raw materials are melted under a protection atmosphere or vacuum condition to achieve homogeneous fusion of all components.

The melting method is not limited. Any melting method is appropriate so long as metals of various components are thoroughly melted and fused. A melting device may also be any type of conventional melting device. In the embodiments of the present application, the melting equipment is preferably an arc melting furnace or an induction melting furnace. That is, the prepared raw materials are placed into an arc furnace water-cooled copper crucible or an induction melting crucible and vacuum-pumped to 6-9×10⁻¹ Pa, and charged with argon of from 0.03 to 0.08 MPa as protection gas. Heating is applied until the materials are melted to form an alloy material whose components are completely homogeneous. The vacuum degree is preferably 8×10⁻¹ Pa, and the argon protection gas is preferably 0.05 MPa.

Step 3: Casting and Cooling to Form an Amorphous Alloy

The melted alloy material is cast into a mold to cool down, so as to obtain the Zr-based amorphous alloy of the foregoing molecular formula according to the corresponding components.

The detailed steps may be as follows: Place a specific amount of prepared master alloy into a high-frequency induction furnace graphite crucible; create a vacuum below 0.1 Pa, and charge argon of 0.05 MPa into the vacuum; heat the graphite crucible until the temperature is higher than the melting point of the alloy material so that the alloy material is completely melted down; turn over the graphite crucible and pour the melt into a copper mold to form amorphous rods; or, by using a die-casting method, lead the alloy into a feeding pool of a die-casting device, and use a die-casting mold to form parts of complex dimensions.

The cooling speed of the cooling processing is 1-10×10 K/second, so as to suppress crystallization and form a cylinder-shaped fully amorphous alloy of a 10 mm critical size.

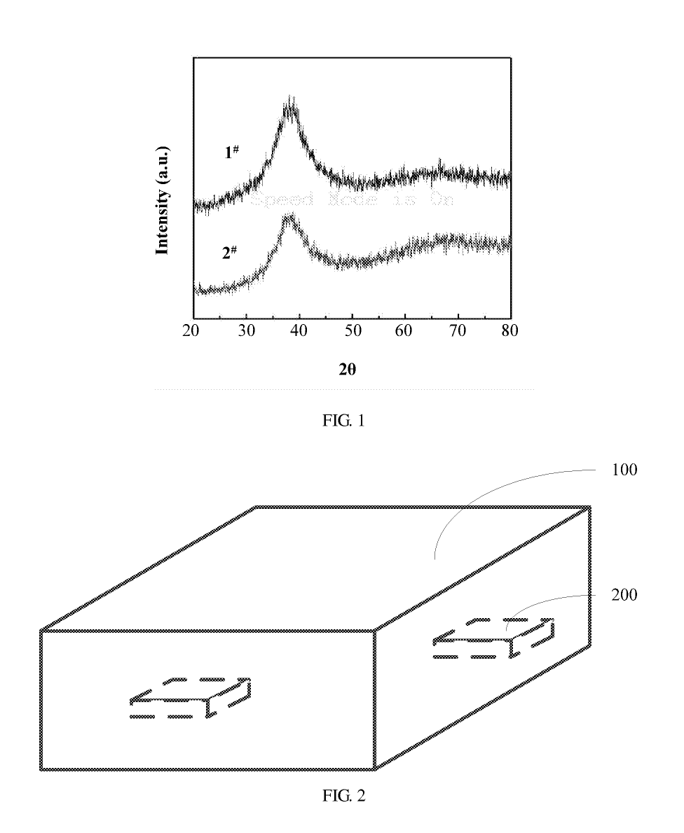

FIG. 1 is an X-ray diffraction (XRD) analysis result diagram of two formulas sampled randomly in the table. The XRD spectrum is a typical amorphous diffuse peak, without a diffraction peak of a crystal phase, indicating that the entire cast bar is a single amorphous phase. In the figure, 1^{#} and 2^{#} represent two sampled formulas Zr₄₉Cu₃₈Al₁₀Ti₂Er₁ (1^{#}) and Zr_{49.7}Ti₂Cu_{38.1}Al₁₀Er_{0.1}Y_{0.1} (2^{#}), where the X coordinate represents an XRD angle (2θ), and the Y coordinate represents relative diffraction intensity.

In the embodiments of the present application, trace quantities of rare earth elements (0.05-5 atomic percent) are added into an alloy to suppress a crystallization trend and improve melt stability; the rare earth elements can absorb oxygen in the alloy, adjust oxygen content of the alloy, suppress heterogeneous nucleation, avoid crystallization of liquid metal in a cooling process, enhance glass forming ability of the alloy, thereby widening the choice range of raw materials required for manufacturing an amorphous alloy. Moreover, a product of a high glass forming ability can be manufactured without using high-purity raw materials, and we can further reduce process requirements such as vacuum degree, which slashes production costs.

### Embodiment 1

Embodiment 1 of the present application provides a Zr-based amorphous alloy, whose components and atomic percents fulfill the following general formula:

ZrₐCu_{b}Ti_{c}Al_{d}Reₑ,

where a, b, c, d, and e are corresponding atomic percent content of elements in the amorphous alloy, 56≦a≦63, 22≦b≦35, 0.1≦c≦4, 7≦d≦13, 0.05≦e≦2, a+b+c+d+e≦100, Re is one or more elements of rare earth, that is, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu. The Re element group may be obtained by adding mishch metal.

Component preparation, melting, casting and cooling are performed according to the general formula and the method for manufacturing a Zr-based amorphous alloy, so as to form a Zr-based amorphous alloy expressed by the general formula.

In this embodiment, Re is preferably one or a combination of plural ones selected from a group of Gd, Er, and Dy. For example, the Zr-based amorphous alloy expressed by the general formula specifically includes Zr₅₇Ti₁Cu₃₁Al₉Gd₂, Zr_{62.85}Ti_{0.2}Cu₂₀Al₁₅Er₂, Zr_{60.5}Ti₂Cu₂₅Al₁₂Er_{0.5}, Zr_{62.85}Cu₂₂Al₁₅Ti_{0.1}Er_{0.05}, Zr_{62.85}Ti_{0.2}Cu₂₀Al₁₅Er₂, Zr₆₀Ti₂Cu₂₅Al₁₂Dy₁, and the like.

### Embodiment 2

Embodiment 2 of the present application provides a Zr-based amorphous alloy, whose components and atomic percents fulfill the following general formula:

ZrₐCu_{b}Ti_{c}Al_{d}Reₑ,

where a, b, c, d, and e are corresponding atomic percent content of elements in the amorphous alloy, 46≦a≦52, 36≦b≦42, 0.1≦c≦4, 7≦d≦13, 0.05≦e≦2, a+b+c+d+e≦100, Re is one or more elements of rare earth, that is, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu. The Re element group may be obtained by adding mishch metal.

Component preparation, melting, casting and cooling are performed according to the general formula and the method for manufacturing a Zr-based amorphous alloy, so as to form a Zr-based amorphous alloy expressed by the general formula.

In this embodiment, preferably, Re is Er and Y, or is one or a combination of plural ones selected from a group of Er, Tm, and Yb. For example, the Zr-based amorphous alloy expressed by the general formula specifically includes Zr₄₉Cu₃₈Al₁₀Ti₂Er₁, Zr_{49.7}Ti₂Cu_{38.1}Al₁₀Er_{0.1}Y_{0.1}, Zr_{49.7}Cu_{37.8}Al₁₀Ti₂Tm_{0.5}, Zr₅₀Cu₃₇Al₁₀Ti₂Yb₁, and the like.

### Embodiment 3

Embodiment 3 of the present application provides a Zr-based amorphous alloy, whose components and atomic percents fulfill the following general formula:

(Zr and/or Hf)ₐCu_{b}Ti_{c}Al_{d}Reₑ,

where a, b, c, d, and e are corresponding atomic percent content of elements in the amorphous alloy, 58≦a≦65, 22≦b≦35, 0.1≦c≦4, 7≦d≦13, 0.05≦e≦2, a+b+c+d+e≦100, Re is one or more elements of rare earth, that is, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu. The Re element group may be obtained by adding mishch metal.

Component preparation, melting, casting and cooling are performed according to the general formula and the method for manufacturing a Zr-based amorphous alloy, so as to form a Zr-based amorphous alloy expressed by the general formula.

In this embodiment, Re is preferably one or a combination of plural ones selected from a group of Er, Yb, Nd, and Tm; the percent content of Hf in (Zr and/or Hf) is from 0 to 8. For example, the Zr-based amorphous alloy expressed by the general formula specifically includes Zr_{59.5} Ti₂Cu₂₅Al₁₂Er_{0.5}Tm_{0.5}Y_{0.5}, Zr_{60.5}Ti₂Cu₂₅Al₁₂Er_{0.5}, Zr_{60.5}Ti₂Cu₂₅Al₁₂Tm_{0.5}, Zr_{60.5}Hf_{0.8}Ti_{1.2}Cu₂₅Al₁₂Er_{0.5}, Zr_{59.5}Hf1Ti₂Cu₂₅Al₁₂Er_{0.5}, Zr_{62.85}Cu₂₂Al₁₅Ti_{0.1}Er_{0.05}, Zr_{60.5}Ti_{1.5}Cu₂₅Al₁₂Yb₁, Zr_{60.5}Hf_{0.8}Ti_{1.2}Cu₂₅Al₁₂Nd_{0.5}, Zr₆₅Cu₂₀Al_{12.9}Ti_{0.1}Er₂, Zr₆₀Hf_{2.9}Cu₂₅Al₁₀Ti_{0.1}Er₂, and the like.

### Embodiment 4

Embodiment 4 of the present application provides a Zr-based amorphous alloy, whose components and atomic percents fulfill the following general formula:

(Zr and/or Hf)ₐCu_{b}Ti_{c}Al_{d}Reₑ,

where a, b, c, d, and e are corresponding atomic percent content of elements in the amorphous alloy, 48≦a≦54, 36≦b≦42, 0.1≦c≦4, 7≦d≦13, 0.05≦e≦2, a+b+c+d+e≦100, Re is one or more elements of rare earth, that is, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu. The Re element group may be obtained by adding mishch metal.

Component preparation, melting, casting and cooling are performed according to the general formula and the method for manufacturing a Zr-based amorphous alloy, so as to form a Zr-based amorphous alloy expressed by the general formula.

In this embodiment, preferably, Re is Er and Y, or is one or a combination of plural ones selected from a group of Er, La, Tm, and Ce; the percent content of Hf in (Zr and/or Hf) is from 0 to 8. For example, the Zr-based amorphous alloy expressed by the general formula specifically includes Zr₄₉Cu₃₈Al₁₀Ti₂Er₁, Zr_{48.7}Hf₁Ti₂Cu_{37.8}Al₁₀(Y and/or Er)_{0.5}, Zr_{49.7}Ti₂Cu_{38.1}Al₁₀Er_{0.1}Y_{0.1}, Zr₅₀Hf₁Ti₂Cu₃₅₁Al₉Ce₃, Zr_{48.7}Hf_{0.6}Cu_{38.45}Ti₂Al₁₀Er_{0.25}, Zr₄₉Hf₁Cu₃₇Al₁₀Ti₂Tm₁, and the like.

### Embodiment 5

Embodiment 5 of the present application provides a Zr-based amorphous alloy, whose components and atomic percents fulfill the following general formula:

(Zr and/or Nb)ₐCu_{b}Ti_{c}Al_{d}Reₑ,

where a, b, c, d, and e are corresponding atomic percent content of elements in the amorphous alloy, 58≦a≦65, 22≦b≦35, 0.1≦c≦4, 7≦d≦13, 0.05≦e≦2, a+b+c+d+e≦100, Re is one or more elements of rare earth, that is, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu. The Re element group may be obtained by adding mishch metal.

Component preparation, melting, casting and cooling are performed according to the general formula and the method for manufacturing a Zr-based amorphous alloy, so as to form a Zr-based amorphous alloy expressed by the general formula.

In this embodiment, Re is preferably one or a combination of plural ones selected from a group of Er, Tm, and Yb; the percent content of Nb in (Zr and/or Nb) is from 0 to 2. For example, the Zr-based amorphous alloy expressed by the general formula specifically includes Zr₅₉Nb₁Cu₂₅Al₁₂Ti₁Er₂, Zr_{60.5}Ti₂Cu₂₅Al₁₂Er_{0.5}, Zr_{62.85}Cu₂₂Al₁₅Ti_{0.1}Er_{0.05}, Zr₆₅Cu₂₀Al_{12.9}Ti_{0.1}Er₂, Zr₅₉Nb₁Cu₂₅Al₁₂Ti₂Tm₁, Zr₅₉Nb₁Cu₂₅Al₁₂Ti₁Yb₂, and the like.

### Embodiment 6

Embodiment 6 of the present application provides a Zr-based amorphous alloy, whose components and atomic percents fulfill the following general formula:

(Zr and/or Nb)ₐCu_{b}Ti_{c}Al_{d}Reₑ,

where a, b, c, d, and e are corresponding atomic percent content of elements in the amorphous alloy, 48≦a≦54, 36≦b≦42, 0.1≦c≦4, 7≦d≦13, 0.05≦e≦2, a+b+c+d+e≦100, Re is one or more elements of rare earth, that is, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu. The Re element group may be obtained by adding mishch metal.

Component preparation, melting, casting and cooling are performed according to the general formula and the method for manufacturing a Zr-based amorphous alloy, so as to form a Zr-based amorphous alloy expressed by the general formula.

In this embodiment, preferably, Re is Er and Y, or is Er and/or Ce; and the percent content of Nb in (Zr and/or Nb) is from 0 to 2.

### Embodiment 7

Embodiment 7 of the present application provides a Zr-based amorphous alloy. In components of the Zr-based amorphous alloy in this embodiment, a part of Cu is replaced with Ni, that is, the Zr-based amorphous alloy has the following formula:

Zrₐ(Cu and/or Ni)_{b}Ti_{c}Al_{d}Reₑ,

where a, b, c, d, and e are atomic percent content of elements in the amorphous alloy, and fulfill 46≦a≦50, 36≦b≦42, 0.1≦c≦5, 7≦d≦13, and 0.05≦e≦2 respectively; or where a, b, c, d, and e are atomic percent content of elements in the amorphous alloy, and fulfill 54≦a≦63, 22≦b≦35, 0.1≦c≦5, 7≦d≦13, and 0.05≦e≦2 respectively.

Re is one or more elements of rare earth, that is, Re is one or a combination of plural ones selected from a group of elements La, Ce, Po, Ho, Er, Nd, Gd, Dy, Sc, Eu, Tm, Tb, Pr, Sm, Yb, and Lu; or Re is combined of Y and one or a combination of plural ones selected from a group of elements La, Ce, Po, Ho, Er, Nd, Gd, Dy, Sc, Eu, Tm, Tb, Pr, Sm, Yb, and Lu. The Re element group may be obtained by adding mishch metal.

Component preparation, melting, casting and cooling are performed according to the general formula and the method for manufacturing a Zr-based amorphous alloy, so as to form a Zr-based amorphous alloy expressed by the general formula.

In this embodiment, Re is preferably one or a combination of plural ones selected from a group of Er, Sc, Tm, Dy, Nd, and Yb; and the percent content of Ni in (Cu and/or Ni) is from 0 to 15. For example, the Zr-based amorphous alloy expressed by the general formula specifically includes Zr_{57.9}Cu₂₅Ni₅Al₁₀Ti_{0.1}SC₂, Zr_{62.85}Cu₂₂Al₁₅Ti_{0.1}Er_{0.05}, Zr₄₉Ti₂Cu₃₆Ni₂Al₁₀Er₁, Zr_{49.5}Ti₂Cu₃₆Ni₂Al₁₀Tm_{0.5}, Zr₆₀Ti2Cu₂₄Ni1Al12Er1, Zr₄₉Ti₂Cu₃₆Ni₂Al₁₀Dy₁, Zr_{60.5}Ti₂Cu₂₄Nl₁Al₁₂Nd_{0.5}, Zr₅₀Ti₁Cu₃₆Ni_{2.5}Al₁₀Yb_{0.5}, and the like.

### Embodiment 8

As shown in FIG. 2, Embodiment 8 of the present application provides an electronic device, where the electronic device includes a casing 100 and electronic components 200 placed in the casing. The casing 100 is made of the foregoing Zr-based amorphous alloy. For example, the Zr-based amorphous alloy that makes up the casing 100 includes Zr, Ti, Cu, Al, and one or more elements of rare earth, in which Zr may be partly replaced with Hf, and Cu may be partly or completely replaced with Ni. An atomic percent of each element in the final amorphous alloy fulfills the following general formula:

(Zr,Hf, and/or Nb)ₐCu_{b}Ti_{c}Al_{d}Reₑ,

where a, b, c, d, and e are corresponding atomic percent content of elements in the amorphous alloy, 40≦a≦65, 20≦b≦50, 0.1≦c≦10, 5≦d≦15, 0.05≦e≦5, a+b+c+d+e≦100, Re is one or more elements of rare earth, that is, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu. In some embodiments, the Re is preferably one or a combination of plural ones selected from a group of elements La, Nd, Dy, Er, Tm, and Yb. The Re element group may be obtained by adding mishch metal.

The casing 100 may be made of the Zr-based amorphous alloy described in any one of Embodiments 1 to 8.

The casing 100 made of the Zr-based amorphous alloy provides high mechanical performance, such as high rigidity, high intensity, and high resilience, and has merits such as low difficulty of making the Zr-based amorphous alloy and relatively low costs.

It should be noted that the components described in the embodiments of the present application do not involve non-metal components such as oxygen and nitrogen, but those skilled in the art know that a certain content of non-metal elements such as oxygen and nitrogen is inevitable in an alloy. For example, in the process of melting a Zr-based amorphous alloy in the embodiment of the present application, oxidation may occur and introduce certain oxygen content, which is inevitable in the current manufacturing process. Therefore, amorphous alloys of homogeneous metal components combined with certain non-metal components shall fall within the protection scope of the present application.

Finally, the foregoing embodiments are merely intended for describing the technical solutions of the embodiments of the present application rather than limiting the present application. Although the embodiments of the present application are described in detail with reference to preferred embodiments, persons of ordinary skill in the art should understand that they may still make modifications to the technical solutions described in the embodiments of the present application or make equivalent replacements to some technical features thereof, without departing from the spirit and scope of the technical solutions of the embodiments of the present application.

What is claimed is:

1. A Zr-based amorphous alloy, wherein the Zr-based amorphous alloy has the following formula:
(Zr,Hf, and/or Nb)ₐCu_{b}Ti_{c}Al_{d}Reₑ,
wherein a, b, c, d, and e are corresponding atomic percent content of elements in the Zr-based amorphous alloy, wherein 40≦a≦65, wherein 20≦b≦50, wherein 0.1≦c≦10, wherein 5≦d≦15, wherein 0.05≦e≦5, wherein a+b+c+d+e≦100, wherein either Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu.

2. The Zr-based amorphous alloy according to claim 1, wherein the Re is one or a combination of plural ones selected from a group of elements La, Ce, Gd, Nd, Dy, Er, Tm, and Yb.

3. The Zr-based amorphous alloy according to claim 1, wherein the Zr-based amorphous alloy has the following formula:
ZrₐCu_{b}Ti_{c}Al_{d}Reₑ,
wherein a, b, c, d, and e are atomic percent content of elements in the amorphous alloy, wherein 56≦a≦63, wherein 22≦b≦35, wherein 0.1≦c≦4, wherein 7≦d≦13, and wherein 0.05≦e≦2.

4. The Zr-based amorphous alloy according to claim 3, wherein the Re is one or a combination of plural ones selected from a group of Gd, Er, and Dy.

5. The Zr-based amorphous alloy according to claim 4, wherein the Zr-based amorphous alloy has one of the following formulas: Zr₅₇Ti₁Cu₃₁Al₉Gd₂, Zr_{62.85}Ti_{0.2}Cu₂₀Al₁₅Er₂, Zr_{60.5}Ti₂Cu₂₅Al₁₂Er_{0.5}, Zr₆₀Ti₂Cu₂₅Al₁₂Dy₁, Zr_{62.85}Cu₂₂Al₁₅Ti_{0.1}Er_{0.05}, and Zr_{62.85}Ti_{0.2}Cu₂₀Al₁₅Er₂.

6. The Zr-based amorphous alloy according to claim 1, wherein the Zr-based amorphous alloy has the following formula:
ZrₐCu_{b}Ti_{c}Al_{d}Reₑ,
wherein a, b, c, d, and e are atomic percent content of elements in the amorphous alloy, wherein 46≦a≦52, wherein 36≦b≦42, wherein 0.1≦c≦4, wherein 7≦d≦13, and wherein 0.05≦e≦2.

7. The Zr-based amorphous alloy according to claim 6, wherein the Re is Er and Y, or wherein Re is one or a combination of plural ones selected from a group of Er, Tm, and Yb.

8. The Zr-based amorphous alloy according to claim 1, wherein the Zr-based amorphous alloy has one of the following formulas: Zr₄₉Cu₃₈Al₁₀Ti₂Er₁, Zr_{49.7}Ti₂Cu_{38.1}Al₁₀Er_{0.1}Y_{0.1}, Zr_{49.7}Cu_{37.8}Al₁₀Ti₂Tm_{0.5}, and Zr₅₀Cu₃₇Al₁₀Ti₂Yb₁.

9. The Zr-based amorphous alloy according to claim 1, wherein the Zr-based amorphous alloy has the following formula:
(Zr and/or Hf)ₐCu_{b}Ti_{c}Al_{d}Reₑ,
wherein a, b, c, d, and e are atomic percent content of elements in the amorphous alloy, wherein 58≦a≦65, wherein 22≦b≦35, wherein 0.1≦c≦4, wherein 7≦d≦13, and wherein 0.05≦e≦2.

10. The Zr-based amorphous alloy according to claim 9, wherein percent content of the Hf is from 0 to 8.

11. The Zr-based amorphous alloy according to claim 10, wherein the Re comprises Y and at least one of Er and Tm, or wherein Re is one or a combination of plural ones selected from a group of Er, Yb, Nd, and Tm.

12. The Zr-based amorphous alloy according to claim 11, wherein the Zr-based amorphous alloy has one of the following formulas: Zr_{59.5}Ti₂Cu₂₅Al₁₂Er_{0.5}Tm_{0.5}Y_{0.5}, Zr_{60.5}Ti₂Cu₂₅Al₁₂Er_{0.5}, Zr_{60.5}Ti₂Cu₂₅Al₁₂Tm_{0.5}, Zr_{60.5}Hf_{0.8}Ti_{1.2}Cu₂₅Al₁₂Er_{0.5}, Zr_{59.5}Hf₁Ti₂Cu₂₅Al₁₂Er_{0.5}, Zr_{62.85}Cu₂₂Al₁₅Ti_{0.1}Er_{0.05}, Zr_{60.5}Ti_{1.5}Cu₂₅Al₁₂Yb₁, Zr_{60.5}Hf_{0.8}Ti_{1.2}Cu₂₅Al₁₂Nd_{0.5}, Zr₆₅Cu₂₀Al_{12.9}Ti_{0.1}Er₂, and Zr₆₀Hf_{2.9}Cu₂₅Al₁₀Ti_{0.1}Er₂.

13. The Zr-based amorphous alloy according to claim 1, wherein the Zr-based amorphous alloy has the following formula:
(Zr and/or Hf)ₐCu_{b}Ti_{c}Al_{d}Reₑ,
wherein a, b, c, d, and e are atomic percent content of elements in the amorphous alloy, and wherein 48≦a≦54, wherein 36≦b≦42, wherein 0.1≦c≦4, wherein 7≦d≦13, and wherein 0.05≦e≦2.

14. The Zr-based amorphous alloy according to claim 13, wherein the Re is Er and Y, or wherein Re is one or a combination of plural ones selected from a group of Er, La, Ce, and Tm.

15. The Zr-based amorphous alloy according to claim 14, wherein percent content of the Hf is from 0 to 8.

16. The Zr-based amorphous alloy according to claim 15, wherein the Zr-based amorphous alloy has one of the following formulas: Zr₄₉Cu₃₈Al₁₀Ti₂Er₁, Zr_{48.7}Hf₁Ti₂Cu_{37.8}Al₁₀(Y and/or Er)_{0.5}, Zr_{49.7}Ti₂Cu_{38.1}Al₁₀Er_{0.1}Y_{0.1}, Zr₅₀Hf₁Ti₂Cu₃₅₁Al₉Ce₃, Zr_{48.7}Hf_{0.6}Cu_{38.45}Ti₂Al₁₀Er_{0.25}, and Zr₄₉Hf₁Cu₃₇Al₁₀Ti₂Tm₁.

17. The Zr-based amorphous alloy according to claim 1, wherein the Zr-based amorphous alloy has the following formula:
(Zr and/or Nb)ₐCu_{b}Ti_{c}Al_{d}Reₑ,
wherein a, b, c, d, and e are atomic percent content of elements in the amorphous alloy, and wherein 58≦a≦65, wherein 22≦b≦35, wherein 0.1≦c≦4, wherein 7≦d≦13, and wherein 0.05≦e≦2.

18. The Zr-based amorphous alloy according to claim 17, wherein percent content of the Nb is from 0 to 2.

19. The Zr-based amorphous alloy according to claim 18, wherein the Re is one or a combination of plural ones selected from a group of Er, Tm, and Yb.

20. The Zr-based amorphous alloy according to claim 19, wherein the Zr-based amorphous alloy has one of the following formulas: Zr₅₉Nb₁Cu₂₅Al₁₂Ti₁Er₂, Zr_{60.5}Ti₂Cu₂₅Al₁₂Er_{0.5}, Zr_{62.85}Cu₂₂Al₁₅Ti_{0.1}Er_{0.05}, Zr₆₅Cu₂₀Al_{12.9}Ti_{0.1}Er₂, Zr₅₉Nb₁Cu₂₅Al₁₂Ti₂Tm₁, and Zr₅₉Nb₁Cu₂₅Al₁₂Ti₁Yb₂.

21. The Zr-based amorphous alloy according to claim 1, wherein the Zr-based amorphous alloy has the following formula:
(Zr and/or Nb)ₐCu_{b}Ti_{c}Al_{d}Reₑ,
wherein a, b, c, d, and e are atomic percent content of elements in the amorphous alloy, and wherein 48≦a≦54, wherein 36≦b≦42, wherein 0.1≦c≦4, wherein 7≦d≦13, and wherein 0.05≦e≦2 respectively.

22. The Zr-based amorphous alloy according to claim 21, wherein the Re is Er and Y, or wherein Re is one or a combination of plural ones selected from a group of Er, Tm, Dy, Nd, and Yb.

23. A Zr-based amorphous alloy, wherein the Zr-based amorphous alloy has the following formula:
Zrₐ(Cu and/or Ni)_{b}Ti_{c}Al_{d}Reₑ,
wherein a, b, c, d, and e are atomic percent content of elements in the amorphous alloy, wherein 46≦a≦50, wherein 36≦b≦42, wherein 0.1≦c≦5, wherein 7≦d≦13, wherein 0.05≦e≦2, wherein a+b+c+d+e≦100, wherein either Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu.

24. A Zr-based amorphous alloy, wherein the Zr-based amorphous alloy has the following formula:
Zrₐ(Cu and/or Ni)_{b}Ti_{c}Al_{d}Reₑ,
wherein a, b, c, d, and e are atomic percent content of elements in the amorphous alloy, wherein 54≦a≦63, wherein 22≦b≦35, wherein 0.1≦c≦5, wherein 7≦d≦13, wherein 0.05≦e≦2, wherein a+b+c+d+e≦100, wherein either Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu.

25. The Zr-based amorphous alloy according to claim 23, wherein the Re is one or a combination of plural ones selected from a group of Er, Sc, Tm, Dy, Nd, and Yb.

26. The Zr-based amorphous alloy according to claim 25, wherein percent content of the Ni is from 0 to 15.

27. The Zr-based amorphous alloy according to claim 25, wherein the Zr-based amorphous alloy has one of the following formulas: Zr_{57.9}Cu₂₅Ni₅Al₁₀Ti_{0.1}Sc₂, Zr_{62.85}Cu₂₂Al₁₅Ti_{0.1}Er_{0.05}, Zr₄₉Ti₂Cu₃₆Ni₂Al₁₀Er₁, Zr_{49.5}Ti₂Cu₃₆Ni₂Al₁₀Tm_{0.5}, Zr₆₀Ti₂Cu₂₄Ni₁Al₁₂Er₁, Zr₄₉Ti₂Cu₃₆Ni₂Al₁₀Dy₁, Zr_{60.5}Ti₂Cu₂₄Ni₁Al₁₂Nd_{0.5}, and Zr₅₀Ti₁Cu₃₆Ni_{2.5}Al₁₀Yb_{0.5}.

28. The Zr-based amorphous alloy according to claim 1, wherein the Zr-based amorphous alloy has one of the following formulas: Zr_{48.7}Hf₁Ti₂Cu_{37.81}Al₁₀Er_{0.5}, Zr_{48.7}Hf₁Ti₂Cu_{37.81}Al₁₀(Y and/or Er)_{0.5}, Zr₅₉Ti₂Cu₂₅₁Al₁₂Er₂, Zr₅₇Ti₂Cu₃₀Al₁₀La₁, Zr₅₇Ti₁Cu₃₁₁Al₉Gd₂, Zr₅₈Cu₂₅Al₁₂Ti₂Hf₁Er₂, Zr₅₉Cu₂₅Al₁₂Ti₁Nb₁Er2, and Zr_{59.5}Hf₁Ti₂Cu₂₅₁Al₁₂Er_{0.5}.

29. A method for manufacturing a Zr-based amorphous alloy, comprising: melting metal raw materials completely under a protection atmosphere or vacuum condition, and then performing casting, cooling, and molding to form a Zr-based amorphous alloy, wherein the Zr-based amorphous alloy has the following formula:
(Zr,Hf and/or Nb)ₐCu_{b}Ti_{c}Al_{d}Reₑ,
wherein a, b, c, d, and e are corresponding atomic percent content of elements in the Zr-based amorphous alloy, 40≦a≦65, 20≦b≦50, 0.1≦c≦10, 5≦d≦15, 0.05≦e≦5, a+b+c+d+e≦100, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu.

30. The manufacturing method according to claim 29, wherein the Re is one or a combination of plural ones selected from a group of elements La, Nd, Dy, Er, Tm, and Yb.

31. An electronic device, comprising a casing and electronic components placed in the casing, wherein the casing is made of a Zr-based amorphous alloy, and the Zr-based amorphous alloy has the following formula:
(Zr,Hf and/or Nb)ₐCu_{b}Ti_{c}Al_{d}Reₑ,
wherein a, b, c, d, and e are corresponding atomic percent content of elements in the Zr-based amorphous alloy, 40≦a≦65, 20≦b≦50, 0.1≦c≦10, 5≦d≦15, 0.05≦e≦5, a+b+c+d+e≦100, Re is one or a combination of plural ones selected from a group of elements La, Ce, Po, Ho, Er, Nd, Gd, Dy, Sc, Eu, Tm, Tb, Pr, Sm, Yb, and Lu, or Re is combined of Y and one or a combination of plural ones selected from a group of elements La, Ce, Po, Ho, Er, Nd, Gd, Dy, Sc, Eu, Tm, Tb, Pr, Sm, Yb, and Lu.
